(19) United States
(12) Patent Application Publication
(10) Pub. No.: US 2024/0274645 A1
(43) Pub. Date: Aug. 15, 2024

(54) DISPLAY DEVICE AND MANUFACTURING METHOD FOR DISPLAY DEVICE

(71) Applicant: Samsung Display Co., LTD., Yongin-si (KR)

(72) Inventors: Han Su KIM, Yongin-si (KR); Eun A YANG, Yongin-si (KR); Woong Bae KIM, Yongin-si (KR)

(21) Appl. No.: 18/426,251

(22) Filed: Jan. 29, 2024

(30) Foreign Application Priority Data
Feb. 15, 2023 (KR) 10-2023-0020024

(51) Int. Cl. H01L 27/15; H01L 33/00; H01L 33/24; H01L 33/44

(52) U.S. Cl. CPC H01L 27/156; H01L 33/005; H01L 33/24; H01L 33/44

(57) ABSTRACT

A display device includes: a bank on a base layer, the bank forming an opening; an alignment electrode layer on the base layer, the alignment electrode layer including a first alignment electrode and a second alignment electrode spaced from each other in a first direction; and a light emitting element between the first alignment electrode and the second alignment electrode. The opening includes a first area and a second area. The first area and the second area are arranged along a second direction different from the first direction. The first area has a first width along the first direction. The second area has a second width along the first direction. The first width is greater than the second width.

### CROSS-REFERENCE TO RELATED APPLICATION

This application claims priority to and the benefit of Korean Patent Application No. 10-2023-0020024, filed on Feb. 15, 2023, in the Korean Intellectual Property Office, the entire content of which is incorporated by reference herein.

### BACKGROUND

### 1. Field

The present disclosure generally relates to a display device and a manufacturing method for a display device.

### 2. Description of the Related Art

Recently, as interest in information displays is increased, research and development of display devices have been continuously conducted.

### SUMMARY

One or more embodiments of the present disclosure provide a display device and a manufacturing method for a display device, which can improve process efficiency.

In accordance with one or more embodiments of the present disclosure, there is provided a display device including: a bank on a base layer, the bank forming an opening; an alignment electrode layer on the base layer, the alignment electrode layer including a first alignment electrode and a second alignment electrode that are spaced from each other in a first direction; and a light emitting element between the first alignment electrode and the second alignment electrode, wherein the opening includes a first area and a second area, wherein the first area and the second area are arranged along a second direction different from the first direction, wherein the first area has a first width along the first direction, and the second area has a second width along the first direction, and wherein the first width is greater than the second width.

In one or more embodiments, the light emitting element may include first light emitting elements and second light emitting elements. The display device may further include an intermediate connection electrode electrically connecting the first light emitting elements and the second light emitting elements to each other. The first light emitting elements may be electrically connected in parallel to each other, and the second light emitting elements may be electrically connected in parallel to each other. The first light emitting elements and the second light emitting elements may be electrically connected in series to each other. The intermediate connection electrode may be located throughout the first area and the second area.

In one or more embodiments, the intermediate connection electrode may overlap with the first area along the first direction.

In one or more embodiments, each of the first light emitting elements and the second light emitting elements may include a first end portion and a second end portion. The first end portion of each of the first light emitting elements and the second light emitting elements may face the second alignment electrode, and the second end portion of each of the first light emitting elements and the second light emitting elements may face the first alignment electrode.

In one or more embodiments, the light emitting element may not be located in the first area and may be located in the second area.

In one or more embodiments, a direction in which the first area and the second area are arranged may be different from a length direction of the light emitting element.

In one or more embodiments, in a plan view, the bank may have an arch-shaped structure in an area overlapping with the second area along the first direction.

In one or more embodiments, the bank may protrude in a thickness direction of the base layer, and include an organic material.

In one or more embodiments, the light emitting element may include first light emitting elements, second light emitting elements, third light emitting elements, and fourth light emitting elements in the second area without being in the first area, and are electrically connected in series with each other. The second area may include a (2-1)th area at one side of the first area and a (2-2)th area at an other side of the first area. The first light emitting elements and the fourth light emitting elements may be in the (2-1)th area, and may be spaced from each other in the first direction. The second light emitting elements and the third light emitting elements may be in the (2-1)th area, and be spaced from each other in the first direction.

In one or more embodiments, the display device may further include a connection electrode layer electrically connected to the light emitting element. The alignment electrode layer may include a first electrode, a second electrode, a third electrode, and a fourth electrode that are sequentially located along the first direction, and each extends in the second direction. Each of the first electrode and the fourth electrode may be the first alignment electrode, and each of the second electrode and the third electrode may be the second alignment electrode. The connection electrode layer may include an anode connection electrode in the (2-1)th area and is electrically connected to the first light emitting elements, a first intermediate connection electrode located throughout the (2-1)th area, the first area, and the (2-2)th area and is electrically connected to the first light emitting elements and the second light emitting elements, a second intermediate connection electrode in the (2-2)th area and is electrically connected to the second light emitting elements and the third light emitting elements, a third intermediate connection electrode located throughout the (2-1)th area, the first area, and the (2-2)th area and is electrically connected to the third light emitting elements and the fourth light emitting elements, and a cathode connection electrode electrically connected to the fourth light emitting elements.

In one or more embodiments of the present disclosure, there is provided a display device including: a pixel circuit layer including a pixel circuit; an alignment electrode layer on the pixel circuit layer; a bank on the pixel circuit layer; a light emitting element aligned on the alignment electrode layer; and a connection electrode layer electrically connected to the light emitting element, wherein the alignment electrode layer includes a first electrode, a second electrode, a third electrode, and a fourth electrode that are sequentially located along a first direction, and extending in a second direction different from the first direction, wherein the bank includes a first area and a second area that are spaced from each other in the second direction, wherein the second area includes a (2-1)th area at one side of the first area and a (2-2)th area at an other side of the first area, and the first area is between the (2-1)th area and the (2-2)th area, wherein the light emitting element includes a first light emitting element, a second light emitting element, a third light emitting element, and a fourth light emitting element located in the second area without being located in the first area, and are electrically connected in series with each other, wherein the connection electrode layer includes an anode connection electrode in the (2-1)th area and is electrically connected to the first light emitting element, a first intermediate connection electrode located throughout the (2-1)th area, the first area, and the (2-2)th area and is electrically connected to the first light emitting element and the second light emitting element, a second intermediate connection electrode in the (2-2)th area and is electrically connected to the second light emitting element and the third light emitting element, a third intermediate connection electrode located throughout the (2-1)th area, the first area, and the (2-2)th area and is electrically connected to the third light emitting element and the fourth light emitting element, and a cathode connection electrode in the (2-1)th area and electrically connected to the fourth light emitting element, and wherein, in a plan view, the bank has an arch-shaped structure in an area overlapping with the second area along the first direction.

In one or more embodiments of the present disclosure, there is provided a method for manufacturing a display device, the method including: forming, on a base layer, an alignment electrode layer including a first alignment electrode and a second alignment electrode that are spaced from each other in a first direction, and a bank forming an opening; providing an ink including a light emitting element in the opening; performing a first drying process on the ink; aligning the light emitting element between the first alignment electrode and the second alignment electrode; and performing a second drying process on the ink.

In one or more embodiments, the first drying process may be performed before the aligning, and the second drying process may be performed after the aligning.

In one or more embodiments, the opening may include a first area and a second area. The first area and the second area may be arranged along a second direction different from the first direction. The first area may have a first width along the first direction, and the second area may have a second width along the first direction. The first width may be greater than the second width.

In one or more embodiments, the method may further include forming a connection electrode layer electrically connected to the light emitting element. The light emitting element may include first light emitting elements and second light emitting elements. The connection electrode layer may include an intermediate connection electrode electrically connecting the first light emitting elements and the second light emitting elements to each other. The first light emitting elements may be electrically connected in parallel to each other, and the second light emitting elements may be electrically connected in parallel to each other. The first light emitting elements and the second light emitting elements may be electrically connected in series to each other. The intermediate connection electrode may be located throughout the first area and the second area.

In one or more embodiments, the forming of the bank may include forming a first bank part overlapping with the first area along the first direction; and forming a second bank part overlapping with the second area along the first direction. The second bank part may have an arch-shaped outer surface.

In one or more embodiments, the performing of the first drying process may include removing the ink in the first area.

In one or more embodiments, the first drying process may be performed until the ink is entirely removed in the first area.

In one or more embodiments, the performing of the first drying process may include allowing the ink to remain in the second area. The performing of the second drying process may include removing the ink in the second area.

In one or more embodiments, the performing of the first drying process may include allowing a capillary force in a direction toward the second area from the first area to be generated.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that the present disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic perspective cutaway view illustrating a light emitting element in accordance with one or more embodiments of the present disclosure.

FIG. 2 is a schematic sectional view illustrating the light emitting element shown in accordance with one or more embodiments of the present disclosure.

FIG. 3 is a schematic plan view illustrating a display device in accordance with one or more embodiments of the present disclosure.

FIG. 4 is a schematic view illustrating a structure including a pixel circuit in accordance with one or more embodiments of the present disclosure.

FIGS. 5 to 7 are schematic plan views illustrating a display device in accordance with one or more embodiments of the present disclosure.

FIGS. 8 to 10 are schematic cross-sectional views taken along the lines A-A′, B-B′, and C-C′ of FIG. 7 illustrating a display device in accordance with one or more embodiments of the present disclosure.

FIG. 11 is a schematic sectional view illustrating a display device in accordance with one or more embodiments of the present disclosure.

FIG. 12 is a schematic flowchart illustrating a manufacturing method for a display device in accordance with one or more embodiments of the present disclosure.

FIGS. 13, 16, 19, 20, 23, and 25 are schematic process plan views illustrating the manufacturing method for the display device in accordance with one or more embodiments of the present disclosure.

FIGS. 14, 15, 17, 18, 21, 22, 24, and 26 are schematic process plan views illustrating the manufacturing method for the display device in accordance with one or more embodiments of the present disclosure.

### DETAILED DESCRIPTION

The present disclosure may apply various changes and different shape, therefore only illustrate in detail with particular examples. However, the examples do not limit to certain shapes but apply to all the change and equivalent material and replacement. The drawings included are illustrated a fashion where the figures are expanded for the better understanding.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

The present disclosure generally relates to a display device and a manufacturing method for display device. Hereinafter, a display device and a manufacturing method for a display device in accordance with one or more embodiments of the present disclosure will be described with reference to the accompanying drawings.

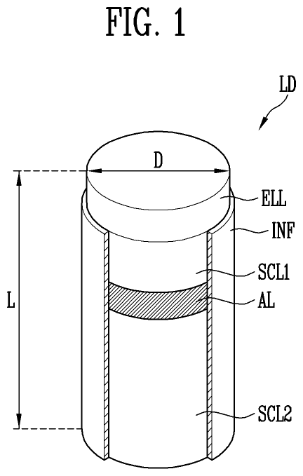

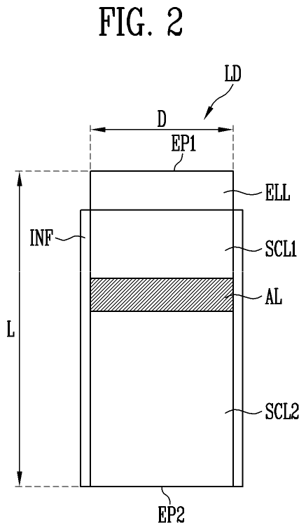

First, a light emitting element LD in accordance with one or more embodiments of the present disclosure will be described with reference to FIGS. 1 and 2. FIG. 1 is a schematic perspective cutaway view illustrating a light emitting element in accordance with one or more embodiments of the present disclosure. FIG. 2 is a schematic sectional view illustrating the light emitting element shown in accordance with one or more embodiments of the present disclosure.

The light emitting element LD is configured to emit light. The light emitting element LD may include a first semiconductor layer SCL1, a second semiconductor layer SCL2, and an active layer AL disposed between the first semiconductor layer SCL1 and the second semiconductor layer SCL2. In accordance with one or more embodiments, the first semiconductor layer SCL1, the active layer AL, and the second semiconductor layer SCL2 may be sequentially stacked along a length L direction of the light emitting element LD. In accordance with one or more embodiments, the light emitting element LD may further include an electrode layer ELL and an insulative film INF.

The light emitting element LD may have various shapes. For example, the light emitting element LD may have a pillar shape extending in one direction. The pillar shape may include a rod-like shape or bar-like shape, which is long in the length L direction (i.e., its aspect ratio is greater than 1), such as a cylinder or a polyprism, and the shape of its section is not particularly limited.

The light emitting element LD may have a first end portion EP1 and a second end portion EP2. In accordance with one or more embodiments, the first semiconductor layer SCL1 may be adjacent to the first end portion EP1 of the light emitting element LD, and the second semiconductor layer SCL2 may be adjacent to the second end portion EP2 of the light emitting element LD. In accordance with one or more embodiments, the electrode layer ELL may be adjacent to the first end portion EP1.

The light emitting element LD may be manufactured by etching sequentially stacked semiconductor layers. The light emitting element LD may have a size of nanometer scale to micrometer scale. For example, each of a diameter D (or width) of the light emitting element LD and a length L may have a range of nanometer scale to micrometer. However, the present disclosure is not necessarily limited thereto.

The first semiconductor layer SCL1 may include a first conductivity type semiconductor. The first semiconductor layer SCL1 may be disposed on the active layer AL, and include a semiconductor layer having a type different from a type of the second semiconductor layer SCL2. For example, the first semiconductor layer SCL1 may include a P-type semiconductor layer. For example, the first semiconductor layer SCL1 may include at least one semiconductor material selected from the group consisting of InAlGaN, GaN, AlGaN, InGaN, AlN, and InN, and include a P-type semiconductor layer doped with a first conductivity type dopant such as Ga, B or Mg. However, the present disclosure is not limited to the above-described example. The first semiconductor layer SCL1 may include various materials.

The active layer AL may be disposed between the first semiconductor layer SCL1 and the second semiconductor layer SCL2. The active layer AL may include and may be a single-quantum well structure or a multi-quantum well structure. The position of the active layer AL is not limited to a specific example, and may be variously changed according to the kind (or type) of the light emitting element LD.

The second semiconductor layer SCL2 may be a second conductivity type semiconductor. The second semiconductor layer SCL2 may be disposed on the active layer AL, and include a semiconductor layer having a type different from the type of the first semiconductor layer SCL1. For example, the second semiconductor layer SCL2 may include an N-type semiconductor layer. For example, the second semiconductor layer SCL2 may include at least one semiconductor material selected from the group consisting of InAlGaN, GaN, AlGaN, InGaN, AlN, and InN, and include an N-type semiconductor layer doped with a second conductivity type dopant such as Si, Ge or Sn. However, the present disclosure is not limited to the above-described example. The second semiconductor layer SCL2 may include various materials.

When a voltage, which is a threshold voltage or higher, is applied to the first end portion EP1 and the second end portion EP2 of the light emitting element LD, electron-hole pairs may be combined in the active layer AL, and the light emitting element LD may emit light. The light emission of the light emitting element LD is controlled by using such a principle, so that the light emitting element LD can be used as a light source for various devices.

The insulative film INF may be disposed on one surface of the light emitting element LD. The insulative film INF may be around (e.g., may surround) an outer surface (e.g., an outer peripheral or circumferential surface) of the active layer AL. In addition, the insulative film INF may further be around (e.g., may further surround) a portion of each of the first semiconductor layer SCL1 and the second semiconductor layer SCL2. The insulative film INF may have a single-layer or a multi-layer structure.

The insulative film INF may expose the first end portion EP1 and the second end portion EP2 of the light emitting element LD, which have different polarities. For example, the insulative film INF may expose one end of each of the electrode layer ELL and the second semiconductor layer SCL2, which are respectively adjacent to the first end portion EP1 and the second end portion EP2 of the light emitting element LD. The insulative film INF can ensure the electrical stability of the light emitting element LD. Also, the insulative film INF reduces or minimizes a surface defect of the light emitting element LD, thereby improving the lifetime and efficiency of the light emitting element LD. In addition, when a plurality of light emitting elements LD are densely disposed, the insulative film INF can prevent a short circuit defect between the light emitting elements LD.

In accordance with one or more embodiments, the insulative film INF may include at least one selected from the group consisting of silicon oxide (SiOₓ), silicon nitride (SiNₓ), silicon oxynitride (SiOₓN_{y}), aluminum oxide (AlOₓ), and titanium oxide (TiOₓ). However, the present disclosure is not necessarily limited to the above-described example.

The electrode layer ELL may be disposed on the first semiconductor layer SCL1. The electrode layer ELL may be adjacent to the first end portion EP1. The electrode layer ELL may be electrically connected to the first semiconductor layer SCL1. A portion of the electrode layer ELL may be exposed. For example, the insulative film INF may expose one surface of the electrode layer ELL. The electrode layer ELL may be exposed in an area corresponding to the first end portion EP1. In accordance with one or more embodiments, a side surface of the electrode layer ELL may be exposed. For example, the insulative film INF may not cover at least a portion of the side surface of the electrode layer ELL while covering a side surface of each of the first semiconductor layer SCL1, the active layer AL, and the second semiconductor layer SCL2. Thus, the electrode layer ELL adjacent to the first end portion EP1 can be easily connected to another component. In accordance with one or more embodiments, the insulating layer INF may expose not only the side surface of the electrode layer ELL but also a portion of a side surface of the first semiconductor layer SCL1 and/or the second semiconductor layer SCL2.

In accordance with one or more embodiments, the electrode layer ELL may be an ohmic contact electrode. However, the present disclosure is not necessarily limited to the above-described example. For example, the electrode layer ELL may be a Schottky contact electrode.

In accordance with one or more embodiments, the electrode layer ELL may be substantially transparent. For example, the electrode layer ELL may include indium tin oxide (ITO). Accordingly, the electrode layer EEL enables emitted light to be transmitted therethrough. However, the present disclosure is not necessarily limited to the above-described example.

The structure, shape, and the like of the light emitting element LD are not limited to the above-described example. In one or more embodiments, the light emitting element LD may have various structures and various shapes. For example, the light emitting element LD may further include an additional electrode layer that is disposed on one surface of the second semiconductor layer SCL2 and is adjacent to the second end portion EP2.

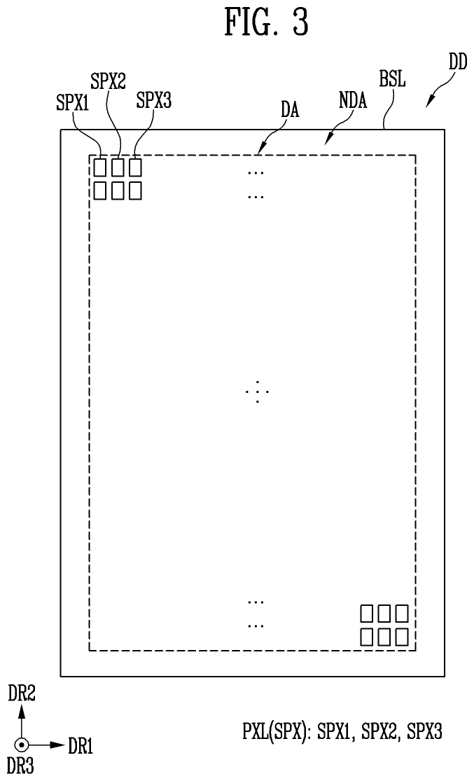

FIG. 3 is a schematic plan view illustrating a display device in accordance with one or more embodiments of the present disclosure.

Referring to FIG. 3, the display device DD may include a base layer BSL and pixels PXL arranged on the base layer BSL. In one or more embodiments, the display device DD may further include a driving circuit (e.g., a scan driver and a data driver) for driving the pixels PXL, lines, and pads.

The display device DD (or the base layer BSL) may include a display area DA and a non-display area NDA around the display area DA along an edge or periphery of the display area DA. The non-display area NDA may refer to an area except the display area DA. The non-display area NDA may surround at least a portion of the display area DA.

The base layer BSL may form a base surface of the display device DD. The base layer BSL may be a rigid or flexible substrate or film. For example, the base layer BSL may be a rigid substrate made of glass or tempered glass, a flexible substrate (or thin film) made of a plastic or metal material, or at least one insulating layer. The material and/or property of the base layer BSL is not particularly limited. In one or more embodiments, the base layer BSL may be substantially transparent. The term “substantially transparent” may mean that light can be transmitted with a desired transmittance (e.g., a predetermined transmittance) or more. In one or more embodiments, the base layer BSL may be translucent or opaque. Also, the base layer BSL may include a reflective material in one or more embodiments.

The display area DA may refer to an area in which the pixels PXL are disposed. The non-display area NDA may refer to an area in which the pixels PXL are not disposed. The driving circuit, the lines, and the pads, which are connected to the pixels PXL of the display area DA, may be disposed in the non-display area NDA.

In accordance with one or more embodiments, the pixels PXL (or sub-pixels SPX) may be arranged according to a stripe arrangement structure, a PENTILE® structure, or the like. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. However, the present disclosure is not limited thereto, and various embodiments may be applied in the present disclosure.

In accordance with one or more embodiments, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may constitute one pixel unit capable of emitting lights of various colors.

For example, each of the first sub-pixel SPX1, the second sub-pixel SPX2, and the third sub-pixel SPX3 may emit light of one color. For example, the first sub-pixel SPX1 may be a red pixel emitting light of red color (e.g., a first color), the second sub-pixel SPX2 may be a green pixel emitting light of green color (e.g., a second color), and the third sub-pixel SPX3 may be a blue pixel emitting light of blue color (e.g., a third color). In accordance with one or more embodiments, a number of second sub-pixels SPX2 may be greater than a number of first sub-pixels SPX1 and a number of third sub-pixels SPX3. However, the color, kind (or type), and/or number of first, second, and third sub-pixels SPX1, SPX2, and SPX3 constituting each pixel unit are not limited to a specific example.

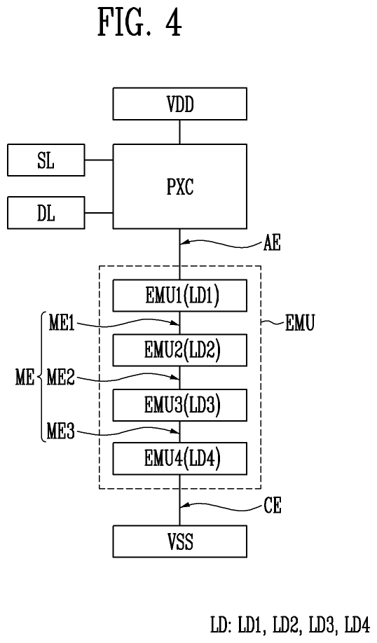

Next, a display device DD including a bank BNK in accordance with one or more embodiments of the present disclosure will be described with reference to FIGS. 4 to 10. In FIGS. 4 to 10, descriptions of portions overlapping with those described above will be simplified or will not be repeated.

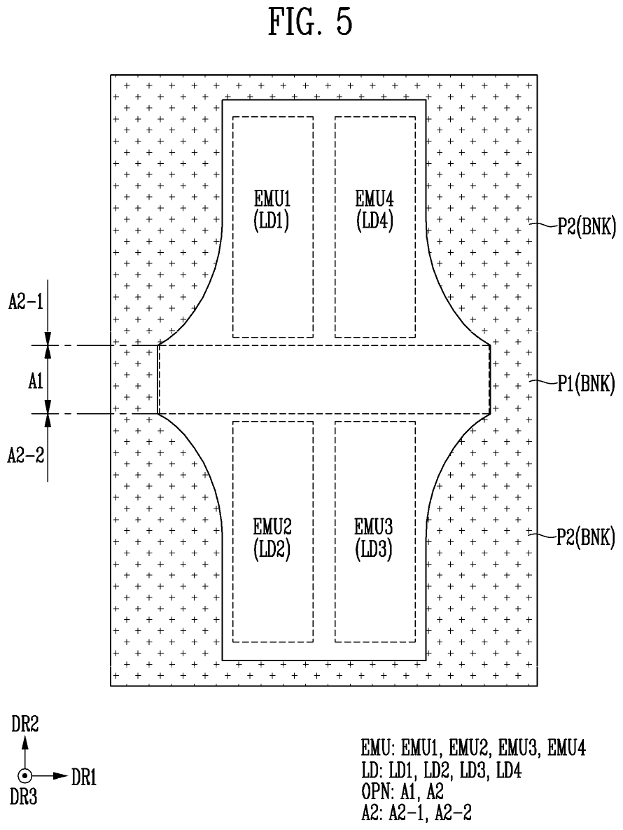

The display device DD in accordance with the embodiments of the present disclosure may include a bank BNK (e.g., see FIG. 5) forming an opening narrowed as approaching in one direction. Light emitting elements LD can be appropriately arranged in an area in which the light emitting elements LD can be normally operated. Thus, process efficiency can be improved, and process cost can be reduced.

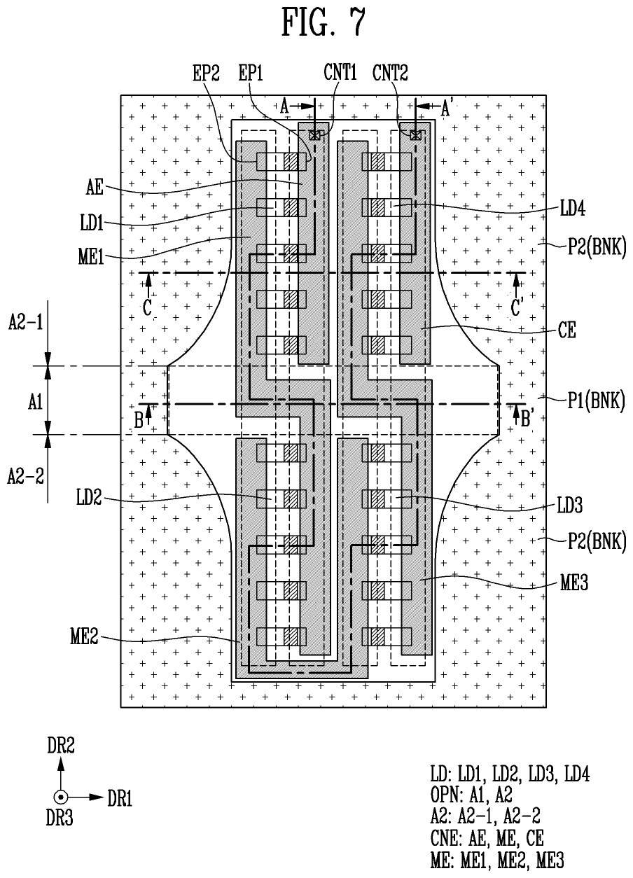

For example, the display device DD may include a light emitting unit EMU including light emitting elements LD and a connection electrode layer CNE (e.g., see FIG. 7). The connection electrode layer CNE may include an anode connection electrode AE, an intermediate connection electrode ME, and a cathode connection electrode CE. The light emitting unit EMU may include one or more light emitting units EMU, and the one or more light emitting units EMU may be electrically connected in series to each other. For example, the one or more light emitting units EMU may be electrically connected to each other through the intermediate connection electrode ME.

Experimentally, when a light emitting element LD is disposed in at least a portion of an area between the one or more light emitting units EMU, the corresponding light emitting element LD may not emit light. However, in accordance with one or more embodiments, the light emitting element LD may be appropriately disposed in an area in which the light emitting element LD can normally emit light due to the structure of the bank BNK, and accordingly, the risk that the light emitting element LD is aligned in an area in which it is difficult for the light emitting element LD to be normally operated can be reduced.

Hereinafter, the above-described technical feature will be described in more detail, based on one or more embodiments in which a light emitting unit EMU includes four light emitting units EMU1, EMU2, EMU3, and EMU4.

FIG. 4 is a schematic view illustrating a structure including a pixel circuit in accordance with one or more embodiments of the present disclosure.

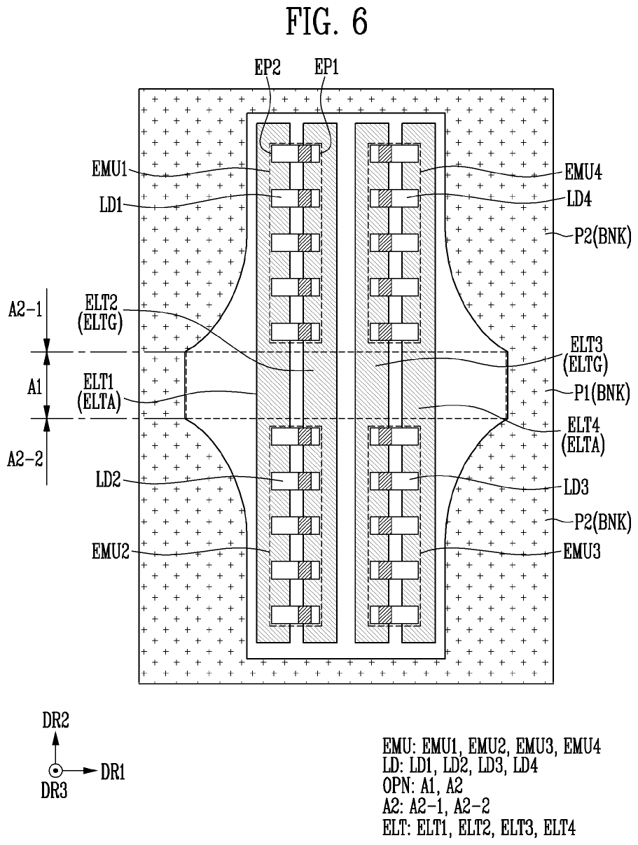

FIGS. 5 to 7 are schematic plan views illustrating a display device in accordance with one or more embodiments of the present disclosure. FIGS. 5 to 7 illustrate the same area. FIG. 5 schematically illustrates a bank BNK and light emitting units EMU in accordance with one or more embodiments of the present disclosure. FIG. 6 schematically illustrates the bank BNK, the light emitting units EMU, and an alignment electrode layer ELT in accordance with one or more embodiments of the present disclosure. FIG. 7 schematically illustrates the bank BNK, the light emitting unit EMU, and a connection electrode layer CNE in accordance with one or more embodiments of the present disclosure.

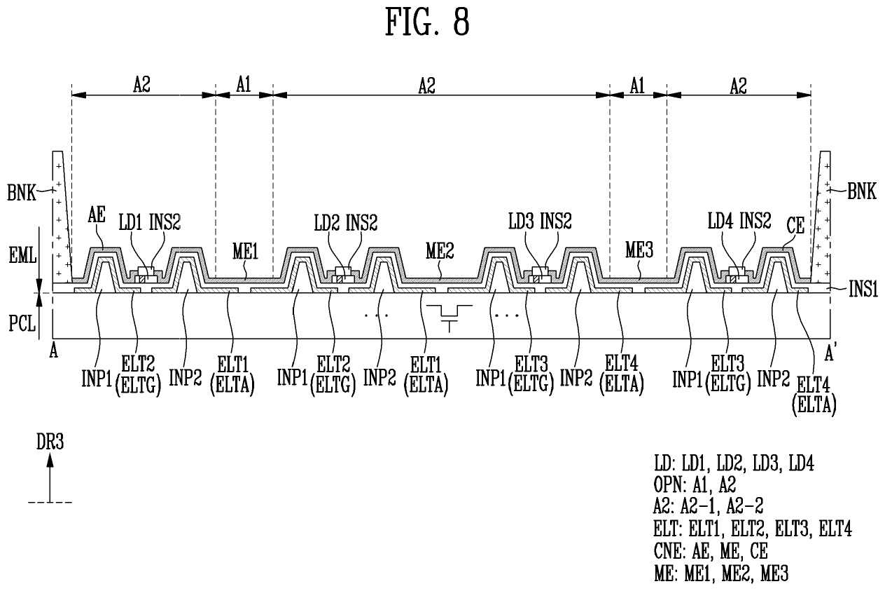

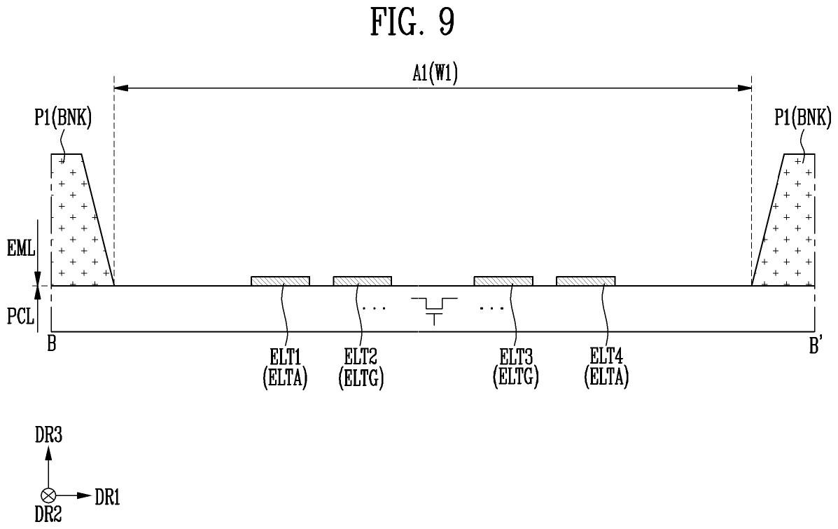

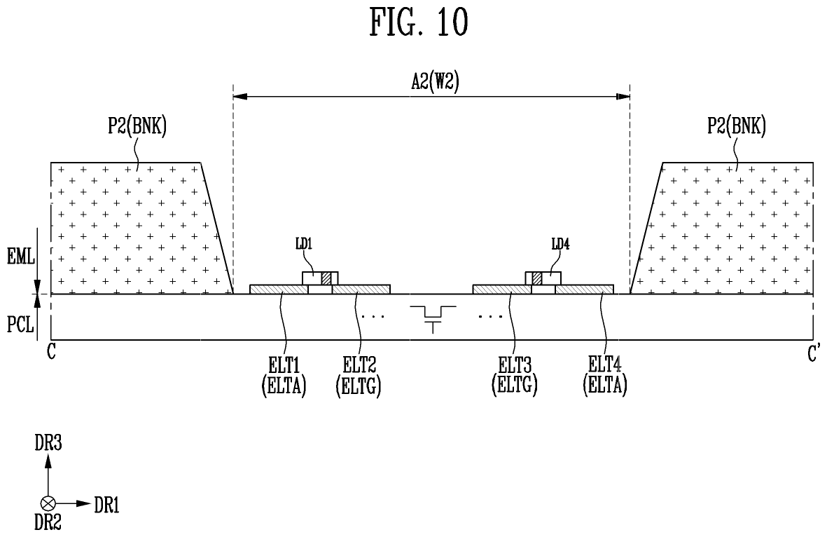

FIGS. 8 to 10 are schematic plan views illustrating a display device in accordance with one or more embodiments of the present disclosure. FIG. 8 is a schematic sectional view taken along the line A-A′ shown in FIG. 7. FIG. 9 is a schematic sectional view taken along the line B-B′ shown in FIG. 7. FIG. 10 is a schematic sectional view taken along the line C-C′ shown in FIG. 7.

The display device DD may include a pixel circuit layer PCL and a light emitting element layer EML. The pixel circuit layer PCL may include a pixel circuit PXC for driving light emitting elements LD. The pixel circuit layer PCL may include a base layer BSL, conductive layers for forming pixel circuits PXC, and insulating layers disposed between the conductive layers.

The light emitting element layer EML may be disposed on the pixel circuit layer PCL. In one or more embodiments, the light emitting element layer EML may include light emitting elements LD. The light emitting elements LD may be aligned on an alignment electrode layer ELT. The light emitting elements LD may form (or constitute) a light emitting unit EMU.

In one or more embodiments, the light emitting unit EMU may include a first light emitting unit EMU1, a second light emitting unit EMU2, a third light emitting unit EMU3, and a fourth light emitting unit EMU4. An intermediate connection electrode ME may include a first intermediate connection electrode ME1, a second intermediate connection electrode ME2, and a third intermediate connection electrode ME3.

The light emitting unit EMU may include light emitting elements LD. For example, the first light emitting unit EMU1 may include first light emitting elements LD1. The second light emitting unit EMU2 may include second light emitting elements LD2. The third light emitting unit EMU3 may include third light emitting elements LD3. The fourth light emitting unit EMU4 may include fourth light emitting elements LD4.

The first light emitting unit EMU1, the second light emitting unit EMU2, the third light emitting unit EMU3, and the fourth light emitting unit EMU4 may be electrically connected in series to each other.

For example, the first light emitting elements LD1 may be electrically connected in parallel to each other, and may be electrically connected in series between the pixel circuit PXC and the second light emitting elements LD2. First end portions EP1 of the first light emitting elements LD1 may be electrically connected to the pixel circuit PXC through an anode connection electrode AE. Second end portions EP2 of the first light emitting elements LD1 may be electrically connected to the second light emitting elements LD2 through the first intermediate connection electrode ME1.

The second light emitting elements LD2 may be electrically connected in parallel to each other, and may be electrically connected in series between the first light emitting elements LD1 and the third light emitting elements LD3. First end portions EP1 of the second light emitting elements LD2 may be electrically connected to the first light emitting elements LD1 through the first intermediate connection electrode ME1. Second end portions EP2 of the second light emitting elements LD2 may be electrically connected to the third light emitting elements LD3 through the second intermediate connection electrode ME2.

The third light emitting elements LD3 may be electrically connected in parallel to each other, and may be electrically connected in series between the second light emitting elements LD2 and the fourth light emitting elements LD4. First end portions EP1 of the third light emitting elements LD3 may be electrically connected to the second light emitting elements LD2 through the second intermediate connection electrode ME2. Second end portions EP2 of the third light emitting elements LD3 may be electrically connected to the fourth light emitting elements LD4 through the third intermediate connection electrode ME3.

The fourth light emitting elements LD4 may be electrically connected in parallel to each other, and may be electrically connected in series between the third light emitting elements LD3 and a second power source VSS. First end portions EP1 of the fourth light emitting elements LD4 may be electrically connected to the third light emitting elements LD3 through the third intermediate connection electrode ME3. Second end portions EP2 of the fourth light emitting elements LD4 may be electrically connected to the second power source VSS through a cathode connection electrode CE.

In one or more embodiments, the first end portion EP1 of each of the first light emitting elements and the second light emitting elements LD1 and LD2 may face a second electrode ELT2 (e.g., a second alignment electrode ELTG). The second end portion EP2 of each of the first light emitting elements and the second light emitting elements LD1 and LD2 may face a first electrode ELT1 (e.g., a first alignment electrode ELTA).

In one or more embodiments, the first end portion EP1 of each of the third and fourth light emitting elements LD3 and LD4 may face a third electrode ELT3 (e.g., a second alignment electrode ELTG). The second end portion EP2 of each of the third and fourth light emitting elements LD3 and LD4 may face a fourth electrode ELT4 (e.g., a first alignment electrode ELTA).

The pixel circuit PXC may include at least one transistor. For example, the pixel circuit PXC may include a driving transistor and a storage capacitor. The at least one transistor may be a thin film transistor (TFT).

The pixel circuit PXC may be electrically connected to a scan line SL and a data line DL. The pixel circuit PXC may be electrically connected to a first power source VDD. The cathode connection electrode CE may be electrically connected to the second power source VSS. The first power source VDD may supply a power voltage having a potential higher than a potential of the second power source VSS. Accordingly, a potential difference is formed between the anode connection electrode AE and the cathode connection electrode CE, so that the light emitting element LD can emit light, based on an electrical signal supplied by the pixel circuit PXC.

In one or more embodiments, the light emitting units EMU may be disposed in an area surrounded by a bank BNK. For example, the bank BNK may form an opening OPN. The bank BNK may be disposed on the pixel circuit layer PCL (or the base layer BSL).

The opening OPN may include an area in which the bank BNK is not disposed. The opening OPN may be an area surrounded by the bank BNK. The bank BNK may protrude in a thickness direction of the base layer BSL (e.g., a third direction DR3) to surround one area, and form the opening OPN.

The bank BNK may include various organic materials. The bank BNK may include an organic material such as acrylic resin, epoxy resin, phenolic resin, polyamide resin, polyimide resin, unsaturated polyester resin, poly-phenylene ether resin, poly-phenylene sulfide resin, and/or benzocyclobutene (BCB). However, the present disclosure is not limited to the above-described example.

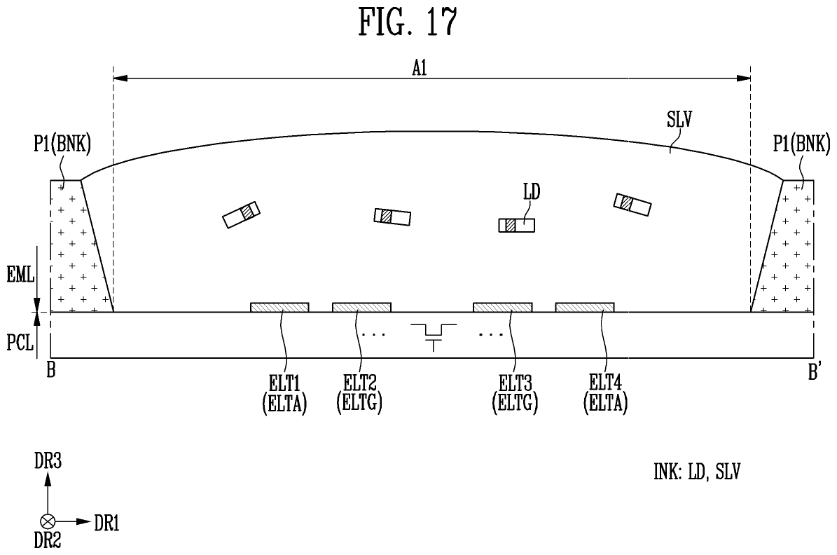

The ink INK (see FIG. 17) including light emitting elements LD may be supplied to the opening OPN defined by the bank BNK, so that the light emitting elements LD are disposed in the opening OPN. The opening OPN may include a first area A1 and a second area A2.

In one or more embodiments, the bank BNK may include first bank parts P1 and second bank parts P2. The first bank parts P1 and the second bank parts P2 may be integrally formed.

The first bank parts P1 may be spaced from each other with the opening OPN interposed therebetween to form the first area A1. The second bank parts P2 may be spaced from each other with the opening OPN interposed therebetween to form the second area A2.

The light emitting units EMU may not be disposed in the first area A1. For example, the first area A1 may not overlap with the light emitting units EMU in a plan view.

The light emitting units EMU may be disposed in the second area A2. For example, the second area A2 may overlap with the light emitting units EMU in a plan view.

The second area A2 may include a (2-1)th area A2-1 and a (2-2)th area A2-2. In one or more embodiments, the first light emitting unit EMU1 (e.g., the first light emitting elements LD1) may be disposed in the (2-1)th area A2-1. The second light emitting unit EMU2 (e.g., the second light emitting elements LD2) may be disposed in the (2-2)th area A2-2. The third light emitting unit EMU3 (e.g., the third light emitting elements LD3) may be disposed in the (2-2)th area A2-2. The fourth light emitting unit EMU4 (e.g., the fourth light emitting element LD4) may be disposed in the (2-1)th area A2-1.

The first light emitting unit EMU1 may be disposed at one side in the (2-1)th area A2-1. The fourth light emitting unit EMU4 may be disposed at the other side in the (2-1)th area A2-1. Accordingly, the first light emitting unit EMU1 and the fourth light emitting unit EMU4 may be spaced from each other along a first direction DR1 in the (2-1)th area A2-1.

The second light emitting unit EMU2 may be disposed at one side in the (2-2)th area A2-2. The third light emitting unit EMU3 may be disposed at the other side in the (2-2)th area A2-2. Accordingly, the second light emitting unit EMU2 and the third light emitting unit EMU3 may be spaced from each other along the first direction DR1 in the (2-2)th area A2-2.

The first area A1 may be disposed between the (2-1)th area A2-1 and the (2-2)th area A2-2. For example, the (2-1)th area A2-1 and the (2-2)th area A2-2 may be spaced from each other along the second direction DR2 crossing the first direction DR1. Accordingly, the first area A1 may overlap with the (2-1)th area A2-1 and the (2-2)th area A2-2 along the second direction DR2.

For example, the first area A1 and the second area A2 may be arranged along a direction in which the first to fourth electrodes ELT1 to ELT4 extend. The first area A1 and the second area A2 may be arranged a direction different from a direction facing the second end portion EP2 from the first end portion EP1 (e.g., a length direction of the light emitting element LD).

In one or more embodiments, the display device DD may include an alignment electrode layer ELT. The alignment electrode ELT may include an electrode structure for aligning light emitting elements LD.

The alignment electrode layer ELT may be disposed on the pixel circuit layer PCL (or the base layer BSL). The alignment electrode layer ELT may include the first electrode ELT1, the second electrode ELT2, the third electrode ELT3, and the fourth electrode ELT4. In one or more embodiments, light emitting elements LD may be aligned between a first alignment electrode ELTA to which a first alignment signal is supplied and a second alignment electrode ELTG to which a second alignment signal different from the first alignment signal is supplied. Each of the first electrode ELT1 and the fourth electrode ELT4 may be the first alignment electrode ELTA. Each of the second electrode ELT2 and the third electrode ELT3 may be the second alignment electrode ELTG.

The first alignment electrode ELTA may be an electrode to which an AC signal can be supplied to align light emitting elements LD. The first alignment electrode ELTA may be an electrode to which an anode signal can be supplied such that light emitting elements LD emit light. The second alignment electrode ELTG may be an electrode to which a ground signal can be supplied to align light emitting elements LD. The second alignment electrode ELTG may be an electrode to which a cathode signal can be supplied such that light emitting elements LD emit light.

The first alignment electrode ELTA and the second alignment electrode ELTG may be supplied (or provided) with the first alignment signal and the second alignment signal in a process of aligning light emitting elements LD. For example, the ink INK including the light emitting elements LD may be supplied (or provided) to the opening OPN, the first alignment signal may be supplied to the first alignment electrode ELTA, and the second alignment signal may be supplied to the second alignment electrode ELTG. The first alignment signal and the second alignment signal may have different waveforms, different potentials, and/or different phases. For example, the first alignment signal may be the AC signal, and the second alignment signal may be the ground signal. However, the present disclosure is not necessarily limited to the above-described example. An electric field may be formed between the first alignment electrode ELTA and the second alignment electrode ELTG, so that the light emitting elements LD are aligned between the first alignment electrode ELTA and the second alignment electrode ELTG, based on the electric field. For example, the light emitting elements LD may be moved (or rotated) by a force (e.g., a dielectrophoresis (DEP) force) according to the electric field to be aligned (or disposed) on the first alignment electrode ELTA and the second alignment electrode ELTG.

In one or more embodiments, the first electrode ELT1, the second electrode ELT2, the third electrode ELT3, and the fourth electrode ELT4 may be sequentially disposed along the first direction DR1, and extend along the second direction DR2. For example, the first electrode ELT1, the second electrode ELT2, the third electrode ELT3, and the fourth electrode ELT4 may extend along a direction in which the first area A and the second area A2 are arranged.

In one or more embodiments, the first electrode ELT1, the second electrode ELT2, the third electrode ELT3, and the fourth electrode ELT4 may be disposed through the first area A1 and the second area A2. For example, each of the first electrode ELT1, the second electrode ELT2, the third electrode ELT3, and the fourth electrode ELT4 may overlap with the first area A1 and the second area A2 in a plan view.

In one or more embodiments, the display device DD may include a first insulating layer INS1 disposed on the alignment electrode layer ELT. The first insulating layer INS1 may cover the first to fourth electrodes ELT1 to ELT4. The first insulating layer INS1 may include at least one selected from the group consisting of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). However, the present disclosure is not limited to the above-described example.

Light emitting elements LD may be disposed (or aligned) on the alignment electrode layer ELT. In one or more embodiments, the light emitting elements LD may be aligned between a first alignment electrode ELTA and a second alignment electrode ELTG in a plan view. First end portions EP1 of the light emitting elements LD may be disposed adjacent to the second alignment electrode ELTG, and second end portions EP2 of the light emitting elements LD may be disposed adjacent to the first alignment electrode ELTA.

The light emitting elements LD may be disposed in the second area A2. The light emitting elements LD may not be disposed in the first area A1. For example, the light emitting elements LD may not overlap with the first area A1 in a plan view.

The light emitting elements LD may not overlap with the first bank part P1 along the first direction DR1. For example, the light emitting elements LD may not overlap with the first bank part P1 along a direction in which the first to fourth electrodes ELT1 to ELT4 are spaced from each other. Each of the light emitting elements LD may not overlap with the first bank part P1 along a direction toward the second end portion EP2 from the first end portion EP1.

In one or more embodiments, the display device DD may further include a second insulating layer INS2. The second insulating layer INS2 may be disposed on a light emitting element LD. The second insulating layer INS2 may cover an active layer AL of the light emitting element LD. The second insulating layer INS2 may expose at least a portion of the light emitting element LD. For example, the second insulating layer INS2 may not cover a first end portion EP1 and a second end portion EP2 of the light emitting element LD. Accordingly, the first end portion EP1 and the second end portion EP2 of the light emitting element LD may be exposed, and may be electrically connected to a connection electrode layer CNE.

When the second insulating layer INS2 is formed on light emitting elements LD after the light emitting elements LD are completely aligned, the light emitting elements LD can be prevented from being separated from positions at which the light emitting elements LD are aligned.

The second insulating layer INS2 may include at least one selected from the group consisting of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). However, the present disclosure is not limited to the above-described example.

At least a portion of the connection electrode layer CNE may be disposed in the opening OPN. For example, at least a portion of the connection electrode layer CNE may be disposed in the first area A1, and at least another portion of the connection electrode layer CNE may be disposed in the second area A2.

For example, the anode connection electrode AE may be disposed at one side in the (2-1)th area A2-1. The cathode connection electrode CE may be disposed at the other side in the (2-1)th area A2-1.

At least one of the intermediate connection electrode ME may be disposed throughout the first area A1 and the second area A2. The first intermediate connection electrode ME1 may be disposed throughout the (2-1)th area A2-1, the first area A1, and the (2-2)th area A2-2. The second intermediate connection electrode ME2 may be disposed in the (2-2)th area A2-2. The third intermediate connection electrode ME3 may be disposed throughout the (2-1)th area A2-1, the first area A1, and the (2-2)th area A2-2.

At least a portion of the intermediate connection electrode ME may be bent once or more. Accordingly, the intermediate connection electrode ME may electrically connect the light emitting units EMU to each other such that the light emitting units EMU form an appropriate electrical path. For example, the first end portions EP1 of the first light emitting elements LD1 may face and may be connected to the anode connection electrode AE, and the second end portion EP2 of the first light emitting elements LD1 may face and may be connected to the first intermediate connection electrode ME1. The first end portions EP1 of the second light emitting elements LD2 may face and may be connected to the first intermediate connection electrode ME1, and the second end portions EP2 of the second light emitting elements LD2 may face and may be connected to the second intermediate connection electrode ME2. The first end portions EP1 of the third light emitting elements LD3 may face and may be connected to the second intermediate connection electrode ME2, and the second end portions EP2 of the third light emitting elements LD3 may face and may be connected to the third intermediate connection electrode ME3. The first end portions EP1 of the fourth light emitting elements LD4 may face and may be connected to the third intermediate connection electrode ME3, and the second end portions EP2 of the fourth light emitting elements LD4 may face and may be connected to the cathode connection electrode CE.

Because it may be difficult for light emitting elements LD in the first area A1 to be electrically connected to each other to appropriately emit light, any light emitting elements LD may not be disposed in the first area A1.

In one or more embodiments, in the first area A1, the first and second alignment electrodes ELTA and ELTG can be disposed, and therefore, light emitting elements LD may be disposed in the first area A1. However, the first area A1 and the second area A2 in accordance with the embodiments of the present disclosure are defined, and thus any light emitting elements LD are not aligned in the first area A1.

For example, the first area A1 may have a width greater than a width of the second area A2. The first area A1 may have a first width W1 in the first direction DR1. The second area A2 may have a second width W2 in the first direction DR1. The first width W1 may be greater than the second width W2. Accordingly, the width of the opening OPN may decrease (may decrease at least for a while) as a distance from the first area A1 increases in the second direction DR2.

In one or more embodiments, the second area A2 may have a width gradually increased as becoming more distant from the first area A1. For example, the second area A2 may have an arch-shaped structure in an area adjacent to the first area A1.

When light emitting elements LD are aligned, the ink INK including the light emitting elements LD may be roughly disposed in the second area A2, and accordingly, the risk that the light emitting elements LD will be aligned in the first area A1 can be decreased.

For example, the ink INK may include a solvent SLV (see FIG. 17) having fluidity. Because the solvent is provided in a liquid phase, the ink INK disposed in the first area A1 may have a tendency to be moved to the second area A2 due to a capillary phenomenon when a portion of the ink INK provided in the opening OPN is removed.

Accordingly, when the ink INK is removed in the first area A1 and is selectively disposed in the second area A2, a process of aligning light emitting elements LD may be performed. Accordingly, the light emitting elements LD can be aligned in the second area A2, and consequently, the alignment efficiency of the light emitting elements LD can be improved.

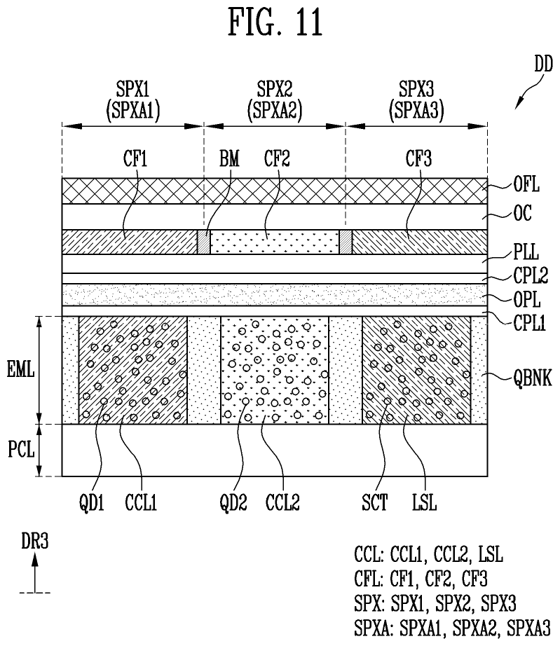

Hereinafter, a sectional structure of the display device DD including components on the light emitting element layer EML in accordance with one or more embodiments of the present disclosure will be described with reference to FIG. 11. In FIG. 11, descriptions of portions overlapping with those described above will be simplified or will not be repeated.

FIG. 11 is a schematic sectional view illustrating a display device in accordance with one or more embodiments of the present disclosure. In FIG. 11, a sectional structure of the display device DD is schematically illustrated based on components disposed on the light emitting element layer EML.

Referring to FIG. 11, sub-pixel areas SPXA respectively corresponding to sub-pixels SPX may be formed in the display area DA. The sub-pixel areas SPXA may include a first sub-pixel area SPXA1 corresponding to a first sub-pixel SPX1, a second sub-pixel area SPXA2 corresponding to a second sub-pixel SPX2, and a third sub-pixel area SPXA3 corresponding to a third sub-pixel SPX3. The first sub-pixel area SPXA1, the second sub-pixel area SPXA2, and the third sub-pixel area SPXA3 may be arranged along the first direction DR1.

An additional bank QBNK may be disposed between the first to third sub-pixel areas SPXA1, SPXA2, and SPXA3 or boundaries of the first to third sub-pixel areas SPXA1, SPXA2, and SPXA3, and define a space (or area) overlapping with each of the first to third sub-pixel areas SPXA1, SPXA2, and SPXA3. The space defined by the additional bank QBNK may be an area in which a color conversion layer CCL can be provided.

The additional bank QBNK may be disposed to surround one area in the light emitting element layer EML. The additional bank QBNK may protrude in the thickness direction of the base layer BSL (e.g., the third direction DR3), thereby defining one area of the additional bank QBNK, and a space in which the color conversion layer CCL can be provided may be formed in the opening OPN.

The additional bank QBNK may include an organic material such as acrylic resin, epoxy resin, phenolic resin, polyamide resin, polyimide resin, unsaturated polyester resin, poly-phenylene ether resin, poly-phenylene sulfide resin, and/or benzocyclobutene. However, the present disclosure is not necessarily limited thereto.

The color conversion layer CCL may be disposed above light emitting elements LD in the space surrounded by the additional bank QBNK. The color conversion layer CCL may include a first color conversion layer CCL1 disposed in the first sub-pixel SPX1, a second color conversion layer CCL2 disposed in the second sub-pixel SPX2, and a light scattering layer LSL disposed in the third sub-pixel SPX3.

The color conversion layer CCL may be disposed above the light emitting elements LD. The color conversion layer CCL may be configured to change a wavelength of light. In accordance with one or more embodiments, the first to third sub-pixels SPX1, SPX2, and SPX3 may include light emitting elements LD emitting light of the same color. For example, the first to third sub-pixels SPX1, SPX2, and SPX3 may include light emitting elements LD emitting light of a third color (or blue). The color conversion layer CCL including color conversion particles is disposed on each of the first to third sub-pixels SPX1, SPX2, and SPX3, so that a full-color image can be displayed.

The first color conversion layer CCL1 may include first color conversion particles for converting light of the third color, which is emitted from the light emitting element LD, into light of a first color. For example, the first color conversion layer CCL1 may include a plurality of first quantum dots QD1 dispersed in a suitable matrix material (e.g., a predetermined matrix material) such as base resin.

In accordance with one or more embodiments, when the light emitting element LD is a blue light emitting element emitting light of blue color, and the first sub-pixel SPX1 is a red pixel, the first color conversion layer CCL1 may include a first quantum dot QD1 for converting light of blue color, which is emitted from the blue light emitting element LD, into light of red color. The first quantum dot QD1 may absorb blue light and emit red light by shifting a wavelength of the blue light according to energy transition. In one or more embodiments, when the first sub-pixel SPX1 is a pixel of another color, the first color conversion layer CCL1 may include a first quantum dot QD1 corresponding to the color of the first sub-pixel SPX1.

The second color conversion layer CCL2 may include second color conversion particles for converting light of the third color, which is emitted from the light emitting element LD, into light of a second color. For example, the second color conversion layer CCL2 may include a plurality of second quantum dots QD2 dispersed in a suitable matrix material (e.g., a predetermined matrix material) such as base resin.

In accordance with one or more embodiments, when the light emitting element LD is a blue light emitting element emitting light of blue color, and the second sub-pixel SPX2 is a green pixel, the second color conversion layer CCL2 may include a second quantum dot QD2 for converting light of blue color, which is emitted from the blue light emitting element, into light of green color. The second quantum dot QD2 may absorb blue light and emit green light by shifting a wavelength of the blue light according to energy transition. In one or more embodiments, when the second sub-pixel SPX2 is a pixel of another color, the second color conversion layer CCL2 may include a second quantum dot QD2 corresponding to the color of the second sub-pixel SPX2.

In accordance with one or more embodiments, light of blue color having a relatively short wavelength in a visible light band is incident into the first quantum dot QD1 and the second quantum dot QD2, so that absorption coefficients of the first quantum dot QD1 and the second quantum dot QD2 can be increased. Accordingly, the efficiency of light finally emitted from the first sub-pixel SPX1 and the second sub-pixel SPX2 can be improved, and excellent color reproduction can be ensured. In addition, the light emitting unit EMU of each of the first to third sub-pixels SPX1, SPX2, and SPX3 is configured by using light emitting elements of the same color (e.g., blue light emitting elements), so that the manufacturing efficiency of the display device DD can be improved.

The light scattering layer LSL may be provided to efficiently use light of the third color (or blue color) emitted from the light emitting element LD. In an example, when the light emitting element LD is a blue light emitting element emitting light of blue color, and the third sub-pixel SPX3 is a blue pixel, the light scattering layer LSL may include at least one kind (or type) of light scattering particle SCT to efficiently use light emitted from the light emitting element LD. In an example, the light scattering particle SCT of the light scattering layer LSL may include various light scattering particles or various light scattering materials. For example, the light scattering particle SCT may include at least one selected from the group consisting of silica (SiOₓ) (e.g., silica bead, hollow silica, or the like), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). However, the present disclosure is not limited thereto.

In one or more embodiments, the light scattering particle SCT is not disposed only in the third sub-pixel SPX3, and may be selectively included in the first color conversion layer CCL1 or the second color conversion layer CCL2. In one or more embodiments, the light scattering particle SCT may be omitted such that the light scattering layer LSL configured with transparent polymer is provided.

A first capping layer CPL1 may be disposed on the color conversion layer CCL. The first capping layer CPL1 may be provided through the first to third sub-pixels SPX1, SPX2, and SPX3. The first capping layer CPL1 may cover the color conversion layer CCL. The first capping layer CPL1 may prevent the color conversion layer CCL from being damaged or contaminated due to infiltration of an impurity such as moisture or air from the outside.

The first capping layer CPL1 is an inorganic layer, and may include at least one selected from the group consisting of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), and silicon oxynitride (SiOₓN_{y}).

An optical layer OPL may be disposed on the first capping layer CPL1. The optical layer OPL may function to improve light extraction efficiency by recycling light provided from the color conversion layer CCL through total reflection. To this end, the optical layer OPL may have a refractive index relatively lower than a refractive index of the color conversion layer CCL. For example, the refractive index of the color conversion layer may be about 1.6 to about 2.0, and the refractive index of the optical layer OPL may be about 1.1 to about 1.3.

A second capping layer CPL2 may be disposed on the optical layer OPL. The second capping layer CPL2 may be provided throughout the first to third sub-pixels SPX1, SPX2, and SPX3. The second capping layer CPL2 may cover the optical layer OPL. The second capping layer CPL2 may prevent the optical layer OPL from being damaged or contaminated due to infiltration of an impurity such as moisture or air from the outside.

The second capping layer CPL2 is an inorganic layer, and may include at least one selected from the group consisting of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), and silicon oxynitride (SiOₓN_{y}).

A planarization layer PLL may be disposed on the second capping layer CPL2. The planarization layer PLL may be provided throughout the first to third sub-pixels SPX1, SPX2, and SPX3.

The planarization layer PLL may include an organic material such as acrylic resin, epoxy resin, phenolic resin, polyamide resin, polyimide resin, unsaturated polyester resin, poly-phenylene ether resin, poly-phenylene sulfide resin, and/or benzocyclobutene. However, the present disclosure is not necessarily limited thereto, and the planarization layer PLL may include various kinds (or types) of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and/or titanium oxide (TiOₓ).

A color filter layer CFL may be disposed on the planarization layer PLL. The color filter layer CFL may include color filters CF1, CF2, and CF3, which accord with a color of each pixel PXL. The color filters CF1, CF2, and CF3, which accord with colors of the respective first to third sub-pixels SPX1, SPX2, and SPX3 are disposed, so that a full-color image can be displayed.

The color filter layer CFL may include a first color filter CF1 disposed in the first sub-pixel SPX1 to allow light emitted from the first sub-pixel SPX1 to be selectively transmitted therethrough, a second color filter CF2 disposed in the second sub-pixel SPX2 to allow light emitted from the second sub-pixel SPX2 to be selectively transmitted therethrough, and a third color filter CF3 disposed in the third sub-pixel SPX3 to allow light emitted from the third sub-pixel SPX3 to be selectively transmitted therethrough.

In accordance with one or more embodiments, the first color filter CF1, the second color filter CF2, and the third color filter CF3 may be respectively a red color filter, a green color filter, and a blue color filter, but the present disclosure is not necessarily limited thereto. Hereinafter, when an arbitrary color filter from among the first color filter CF1, the second color filter CF2, and the third color filter CF3 is designated or when two or more kinds (or types) of color filters are inclusively designated, the corresponding color filter or the corresponding color filters are referred to as a “color filter CF” or “color filters CF.”

The first color filter CF1 may overlap with the first color conversion layer CCL in the thickness of the base layer BSL (e.g., the third direction DR3). The first color filter CF1 may include a color filter material for allowing light of a first color (or red) to be selectively transmitted therethrough. For example, when the first sub-pixel SPX1 is a red pixel, the first color filter CF1 may include a red color filter material.

The second color filter CF2 may overlap with the second color conversion layer CCL2 in the thickness of the base layer BSL (e.g., the third direction DR3). The second color filter CF2 may include a color filter material for allowing light of a second color (or green) to be selectively transmitted therethrough. For example, when the second sub-pixel SPX2 is a green pixel, the second color filter CF2 may include a green color filter material.

The third color filter CF3 may overlap with the light scattering layer LSL in the thickness of the base layer BSL (e.g., the third direction DR3). The third color filter CF3 may include a color filter material for allowing light of a third color (or blue) to be selectively transmitted therethrough. For example, when the third sub-pixel SPX3 is a blue pixel, the third color filter CF3 may include a blue color filter material.

In one or more embodiments, a light blocking layer BM may be further disposed between the first to third color filters CF1, CF2, and CF3. As described above, when the light blocking layer BM is formed between the first to third color filters CF1, CF2, and CF3, a color mixture defect viewed at the front or side of the display device DD can be prevented. The material of the light blocking layer BM is not particularly limited, and the light blocking layer BM may be configured with various light blocking materials. In an example, the light blocking layer BM may include a black matrix, or may be implemented by stacking the first to third color filters CF1, CF2, and CF3.

An overcoat layer OC may be disposed on the color filter layer CFL. The overcoat layer OC may be provided throughout the first to third sub-pixels SPX1, SPX2, and SPX3. The overcoat layer OC may cover a lower member including the color filter layer CFL. The overcoat layer OC may prevent moisture or air from infiltrating into the above-described lower member. Also, the overcoat layer OC may protect the above-described lower member from a foreign matter such as dust.

The overcoat layer OC may include an organic material such as acrylic resin, epoxy resin, phenolic resin, polyamide resin, polyimide resin, unsaturated polyester resin, poly-phenylene ether resin, poly-phenylene sulfide resin, and/or benzocyclobutene. However, the present disclosure is not necessarily limited thereto, and the overcoat layer OC may include various kinds (or types) of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and/or titanium oxide (TiOₓ).

An outer film layer OFL may be disposed on the overcoat layer OC. The outer film layer OFL may be disposed at an outer portion of the display device 100, to reduce external influence. The outer film layer OFL may be provided throughout the first to third sub-pixels SPX1, SPX2, and SPX3. In one or more embodiments, the outer film layer OFL may include at least one of a polyethylenephthalate (PET) film, a low reflective film, a polarizing film, and/or a transmittance controllable film, but the present disclosure is not necessarily limited thereto. In one or more embodiments, the pixel PXL may include an upper substrate instead of the outer film layer OFL.

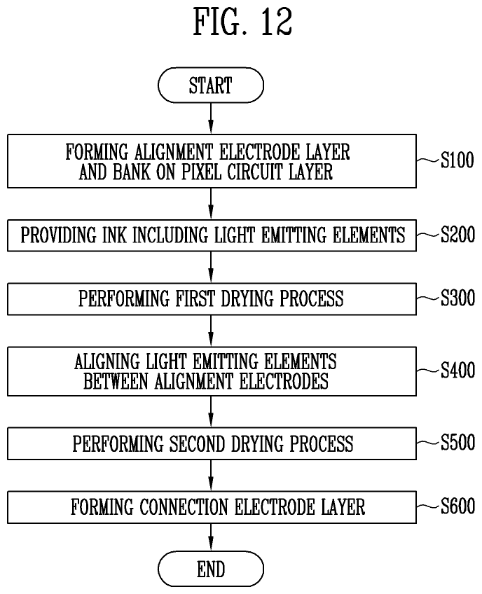

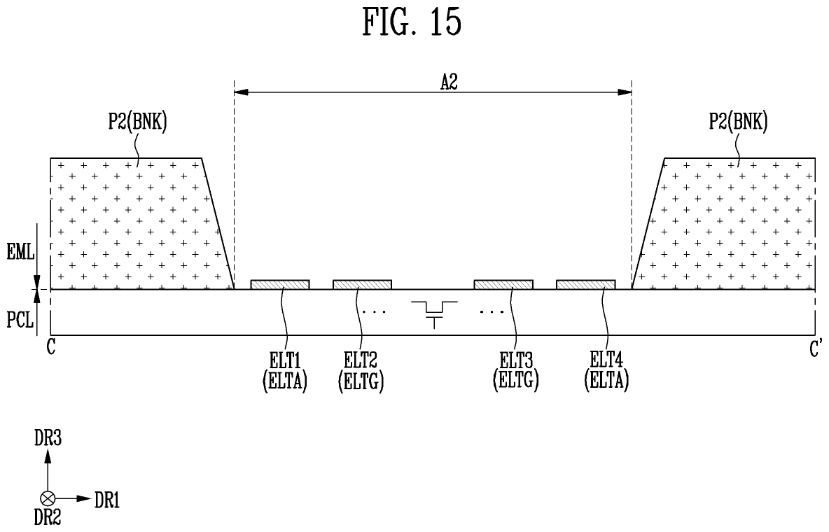

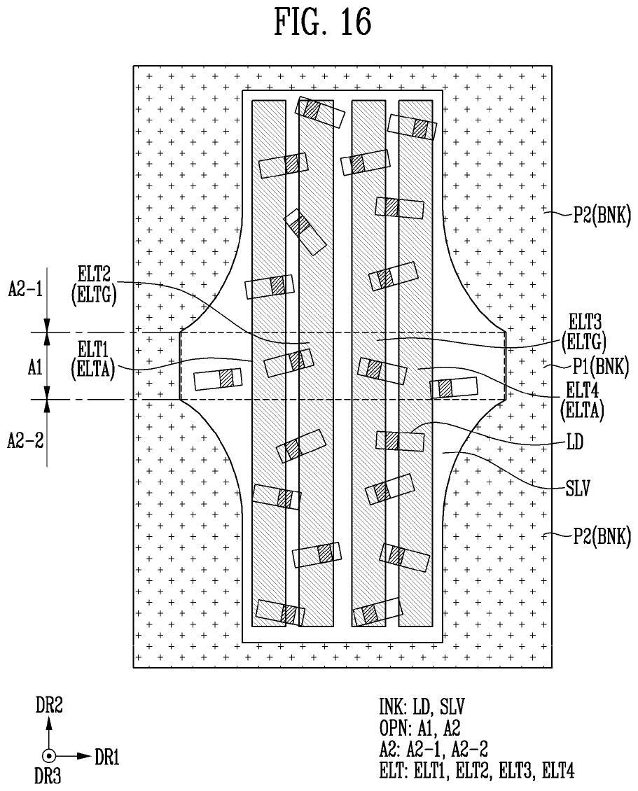

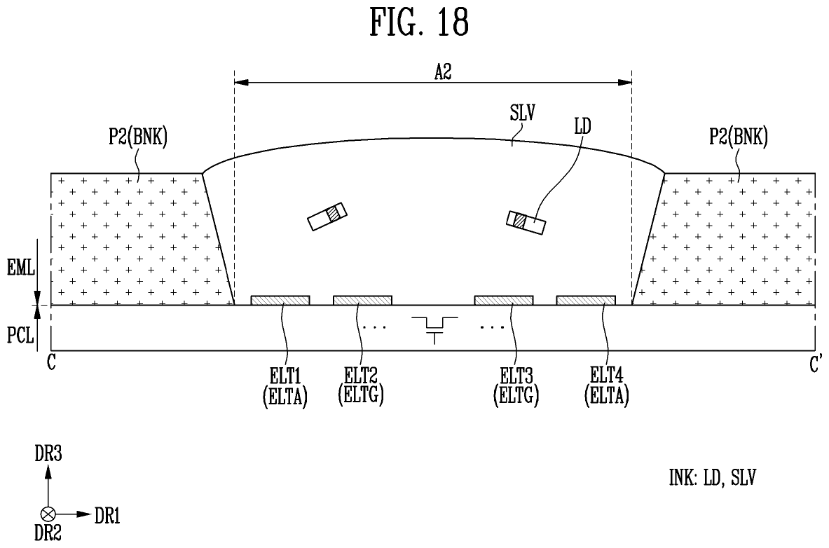

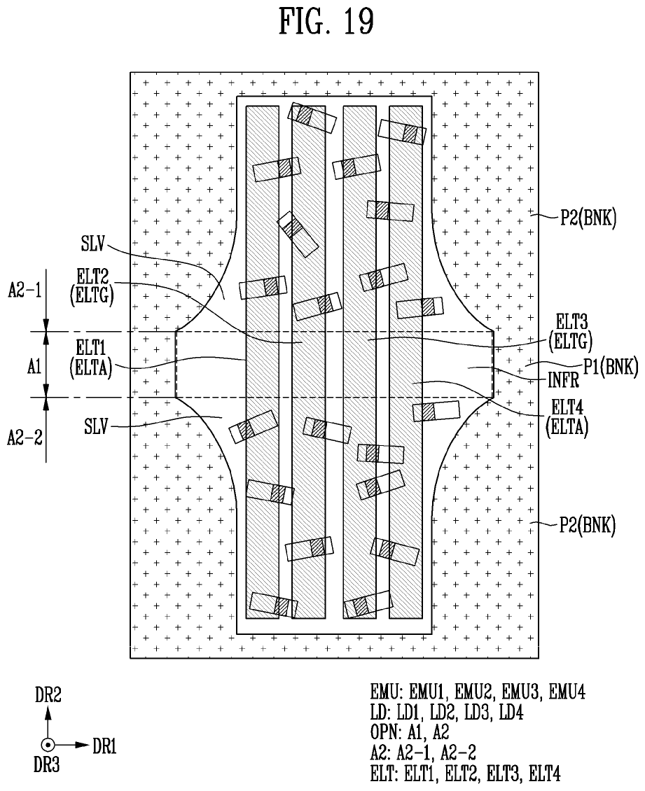

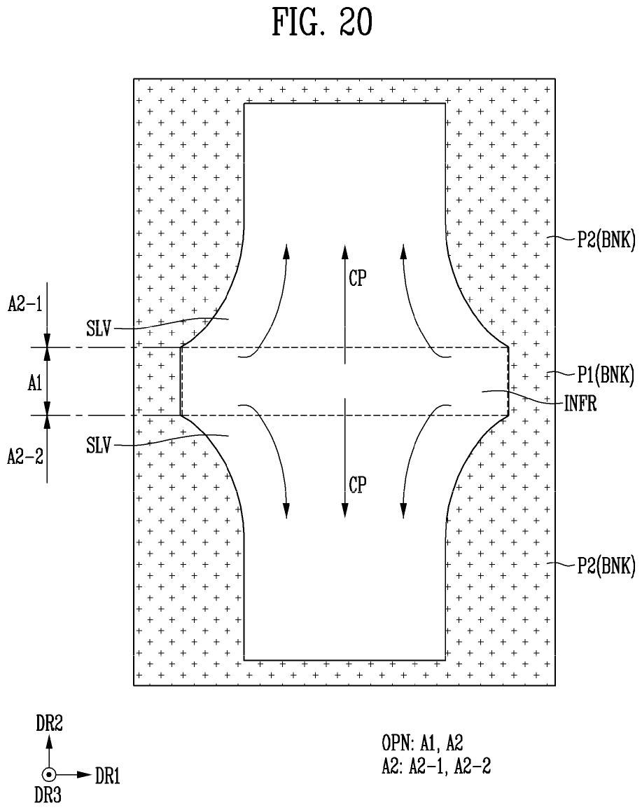

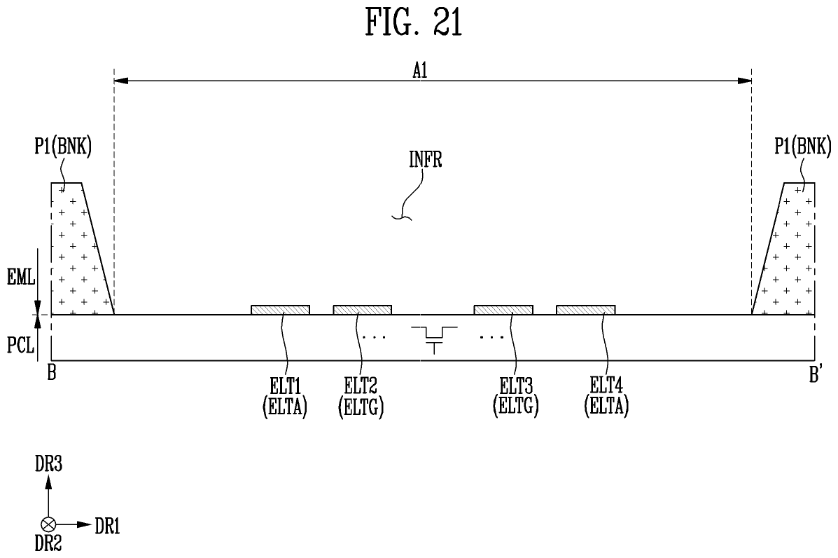

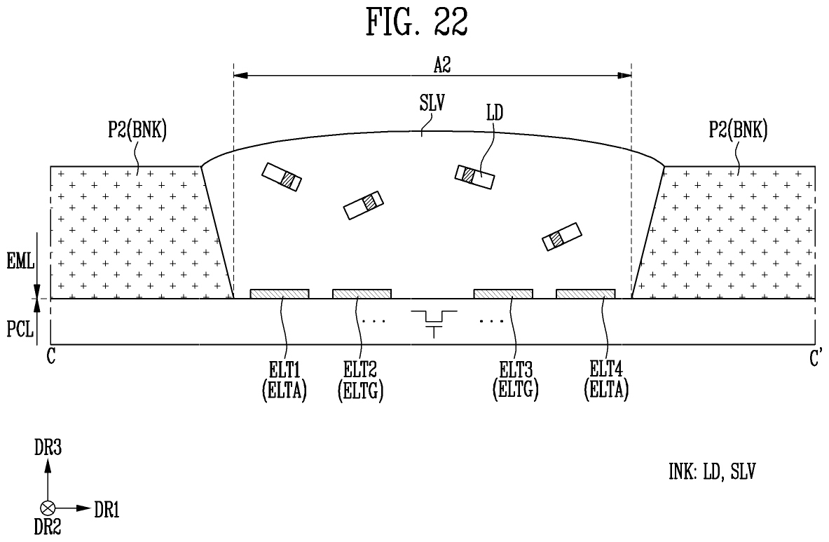

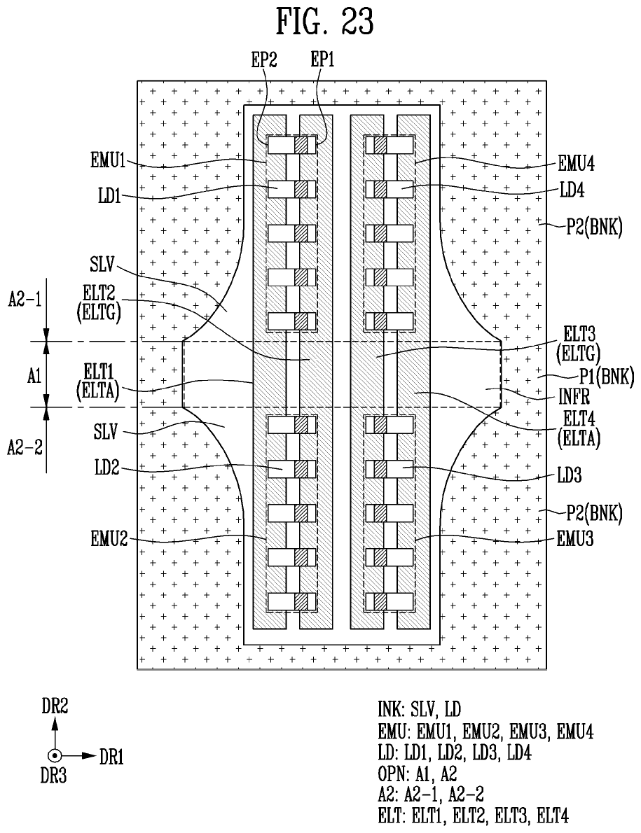

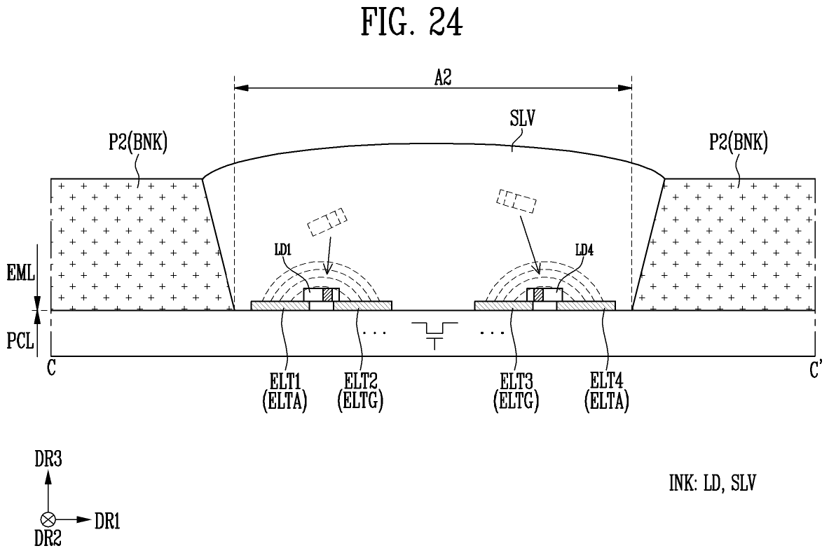

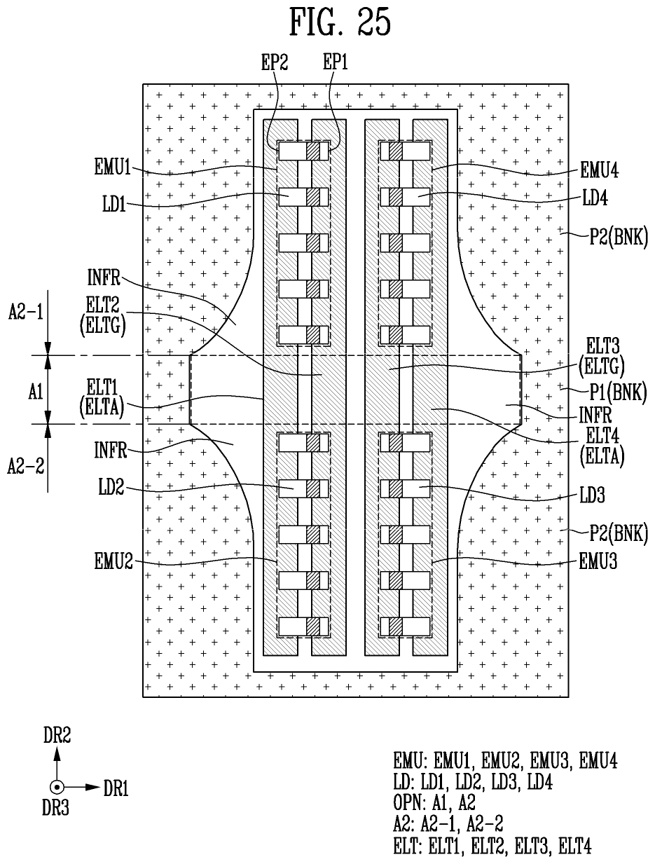

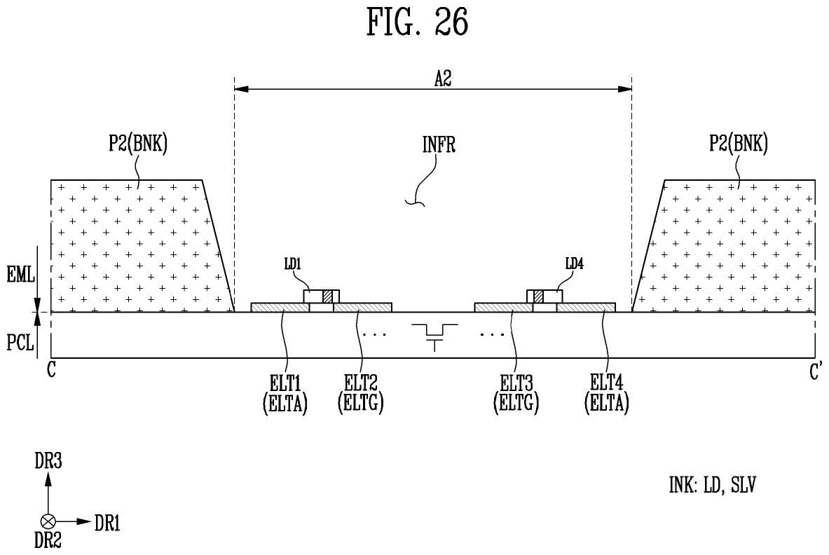

Hereinafter, a manufacturing method for a display device DD in accordance with one or more embodiments of the present disclosure will be described with reference to FIGS. 12 to 26. In FIGS. 12 to 26, descriptions of portions overlapping with those described above will be simplified or will not be repeated.

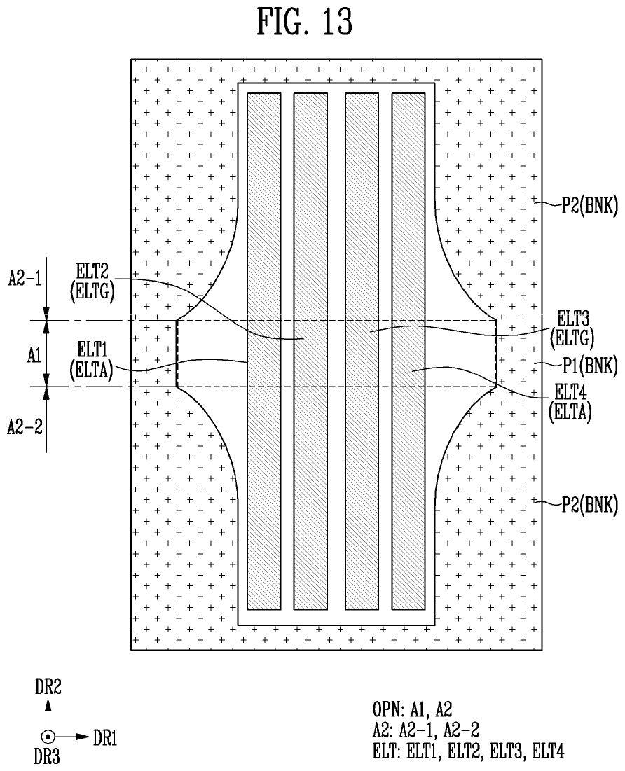

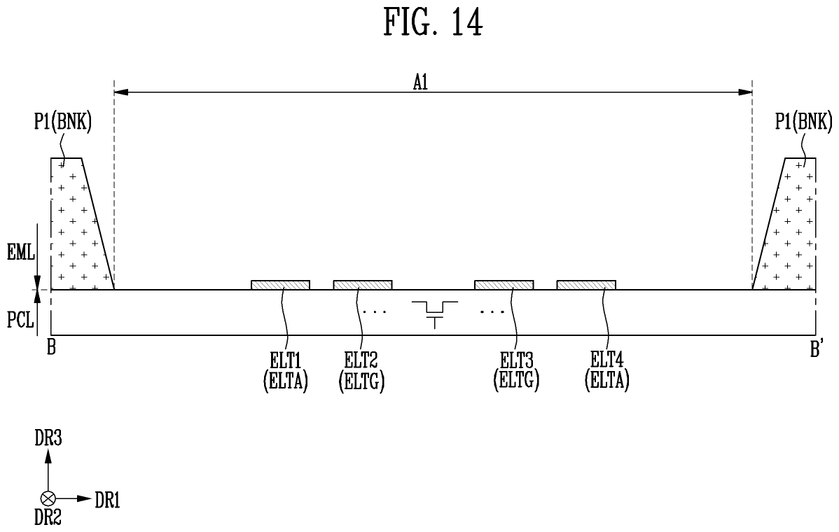

FIG. 12 is a schematic flowchart illustrating a manufacturing method for the display device in accordance with one or more embodiments of the present disclosure. FIGS. 13, 16, 19, 20, 23, and 25 are schematic process plan views illustrating the manufacturing method for the display device in accordance with one or more embodiments of the present disclosure. FIGS. 14, 15, 17, 18, 21, 22, 24, and 26 are schematic process plan views illustrating the manufacturing method for the display device in accordance with one or more embodiments of the present disclosure.

Referring to FIG. 12, the manufacturing method for the display device DD may include step S100 of forming an alignment electrode layer and a bank on a pixel circuit layer, step S200 of providing an ink including light emitting elements, step S300 of performing a first drying process, step S400 of aligning light emitting elements between alignment electrodes, step S500 of performing a second drying process, and step S600 of forming a connection electrode layer.

Referring to FIGS. 12 to 15, in the step S100 of forming the alignment electrode layer and the bank on the pixel circuit layer, a pixel circuit layer PCL may be manufactured, and an alignment electrode layer ELT and a bank BNK may be patterned on the pixel circuit layer PCL.

In the present disclosure, conductive layers and insulating layers may be formed by patterning a conductive layer (or metal layer), an inorganic material, an organic material, or the like through a process using an ordinary mask. For example, the conductive layers and the insulating layers may be patterned to form the pixel circuit layer PCL, so that a pixel circuit PXC is manufactured.

In this step, after a conductive layer for forming the alignment electrode layer ELT is deposited on the pixel circuit layer PCL, the deposited conductive layer may be etched, so that the alignment electrode layer ELT is manufactured. In one or more embodiments, a first insulating layer INS1 for covering the alignment electrode layer ELT may be disposed after the alignment electrode layer ELT is patterned.

In this step, a first electrode ELT1, a second electrode ELT2, a third electrode ELT3, and a fourth electrode ELT4 may be sequentially patterned along the first direction DR1. The first electrode ELT1, the second electrode ELT2, the third electrode ELT3, and the fourth electrode ELT4 may be patterned to extend along a direction in which a first area A1 and a second area A2 are arranged.

In this step, the bank BNK may be patterned on the pixel circuit layer PCL (or the first insulating layer INS1). For example, the bank BNK may be disposed to form an opening OPN. In order to manufacture the bank BNK, a first bank part P1 which forms the opening OPN having a relatively wide width in the first direction DR1 and a second bank part P2 which forms the opening OPN having a relatively narrow width in the first direction DR1 may be patterned.

In this step, the second area A2 defined by the second bank part P2 may have a width narrowed as becoming more distant along the second direction DR2 from the first area A1. To this end, the second bank part P2 may be patterned to have an arch shape (or an arched outer surface).

Referring to FIGS. 12 and 16 to 18, in the step S200 of providing the ink including the light emitting elements, the ink INK may be supplied onto a base layer BSL (or the alignment electrode layer ELT). In one or more embodiments, the ink INK may be provided by a printing apparatus capable of spraying a fluid.

In accordance with one or more embodiments, the printing apparatus may include a nozzle device configured to release a liquid fluid to the outside. The ink INK defined in the present disclosure may refer to a liquid mixture that can be released by the printing apparatus. The printing apparatus may spray the ink INK while moving above an area in which light emitting elements are to be arranged.

In accordance with one or more embodiments, the ink INK may include a solvent SLV and a light emitting element LD. The light emitting element LD may be provided in plurality, to be included in the solvent SLV having a fluidic property. For example, in one or more embodiments, the solvent SLV may have a fluidic property, and accordingly, the light emitting elements LD may be dispersed in the solvent SLV. The solvent SLV may refer to a fluidic material instead of a solid phase material. The fluidic material allows the light emitting elements LD to be dispersed and provided therein. In one or more embodiments, the solvent SLV may include an organic solvent. For example, the solvent SLV may include at least one selected from the group consisting of Propylene Glycol Methyl Ether Acetate (PGMEA), Dipropylene Glycol n-Propyl Ether (DGPE), and Triethylene Glycol n-Butyl Ether (TGBE). However, the present disclosure is not limited to the above-described example, and the solvent SLV may include various organic solvents.

In this step, the ink INK may be accommodated in the opening OPN formed by the bank BNK. The light emitting elements LD included in the ink INK may be provided in a state in which the light emitting elements LD are randomly located in the opening OPN. For example, the ink INK may be disposed in the first area A1 and may be disposed in the second area A2. Accordingly, in this step, the light emitting elements LD may be disposed in the first area A1 and the second area A2.

Referring to FIGS. 12 and 19 to 22, in the step S300 of performing the first drying process, at least a portion of the ink INK may be removed. In one or more embodiments, the first drying process may be a preliminary drying process.

In this step, a portion of the ink INK in the opening OPN may be removed, and another portion of the ink INK may remain.

For example, the present disclosure may include a feature in which the ink INK is sequentially removed through a plurality of drying process defined as individual steps.

Accordingly, in this step, the first drying process may be performed, and a second drying process different from the first drying process may be performed after the light emitting elements LD are aligned.

In the present disclosure, an amount of the ink INK removed in a drying process may be adjusted by controlling a temperature, a pressure, and a time, wherein the drying process is performed. For example, as the temperature becomes higher, the speed at which the ink INK is removed may become higher at the same pressure for the same time. As the time for which the drying process is performed is increased, the amount of the ink INK removed may be increased. In the present disclosure, the temperature, pressure, and time of a process environment in which the drying process is performed are not necessarily limited to a specific example. In order for the first drying process to be appropriately performed, the drying process may be performed until an appropriate amount of the ink INK remains under a process environment having one temperature and one pressure.

In this step, at least a portion of the ink INK may be removed. The ink INK may have a tendency to travel to the second area A2 from the first area A1. For example, because the second area A2 has a width narrower than a width of the first area A1 in the first direction DR1, a force CP according to a capillary phenomenon may be generated in the ink INK in the opening OPN.

The force CP according to the capillary phenomenon may tend to be directed towards the second area A2 from the first area A1. In one or more embodiments, a direction of the force CP according to the capillary phenomenon may be determined by the arch shape of the second bank part P2.

As the first drying process is performed, the ink INK may be first removed in the first area A1. Accordingly, the first area A1 may be provided as an ink free area INFR in which the ink INK does not remain. Although the first drying process is performed, the ink INK may still remain in the second area A2. As a result, thanks to the structural feature of the bank BNK in accordance with one or more embodiments of the present disclosure, the ink INK can be selectively removed in the first area A1 as the first drying process is performed.

The first drying process may be performed until the ink INK is entirely removed in the first area A1. For example, after the first drying process is performed, the ink INK may be removed by 10 vol % to 30 vol % with respect to an initial input amount. However, the present disclosure is not limited to the above-described numerical range.

Referring to FIGS. 12, 23, and 24, the step S400 of aligning light emitting elements LD between the alignment electrodes, the light emitting elements LD may be aligned between a first alignment electrode ELTA and a second alignment electrode ELTG.

In this step, an electrical signal (e.g., an alignment signal) may be provided to the first and second alignment electrodes ELTA and ELTG, so that an electric field is formed in an area between the first and second alignment electrodes ELTA and ELTG in which the light emitting elements LD are to be aligned. For example, a first alignment signal may be supplied to the first alignment electrode ELTA, and a second alignment signal may be applied to the second alignment electrode ELTG. In one or more embodiments, the first alignment signal may be an AC signal, and the second alignment signal may be a ground signal. Alternatively, the first alignment signal may be the ground signal, and the second alignment signal may be the AC signal. However, the present disclosure is not necessarily limited to the above-described example. The AC signal may be at least one of a sine wave, a triangular wave, a square wave, a trapezoidal wave, and a pulse wave. However, the present disclosure is not limited thereto, and the AC signal may have various AC signal forms known in the art.

In accordance with one or more embodiments, the light emitting elements LD may be moved (or rotated) by a force (e.g., a dielectrophoresis (DEP) force) according to the electric field, to be aligned on the first and second alignment electrodes ELTA and ELTG (or the first insulating layer INS1). Each of a first electrode ELT1 and a fourth electrode ELT4 may be the first alignment electrode ELTA, and each of a second electrode ELT2 and a third electrode ELT3 may be the second alignment electrode ELTG.

In this step, the light emitting elements LD may be aligned on the alignment electrode layer ELT in the second area A2. As described above, as the first drying process is performed, the ink INK may be disposed in the second area A2 without being disposed in the first area A1. Therefore, the light emitting elements LD may be disposed in the second area A2 without being disposed in the first area A1. Thus, the light emitting elements LD can be aligned in an area in which the light emitting elements LD can emit light, and the risk that the light emitting elements LD are disposed in an area in which it is difficult for the light emitting elements LD to be normally operated can be reduced. As a result, the alignment of the light emitting elements LD can be improved, and process cost for the light emitting elements LD can be saved.

Referring to FIGS. 12, 25, and 26, in the step S500 of performing the second drying process, the remaining ink INK may be removed. In one or more embodiments, the second drying process may be a main drying process.

In this step, as the remaining ink INK is removed after the light emitting elements LD are aligned, the ink INK may not exist in the opening OPN. Accordingly, like the first area A1, the second area A2 may be provided as an ink free area INFR. In one or more embodiments, the second drying process may be performed in a manner similar to the manner of the first drying process.

In one or more embodiments, an amount of the ink INK removed in the second drying process may be greater than an amount of the ink INK removed in the first drying process.

Referring to FIG. 12 in conjunction with FIGS. 7 and 8 described above, in the step S600 of forming the connection electrode layer, a connection electrode layer CNE electrically connected to the light emitting elements LD may be patterned.

In this step, an anode connection electrode AE, an intermediate connection electrode ME, and a cathode connection electrode CE may be patterned. Accordingly, an electrical path through which the light emitting elements LD normally emit light may be formed. In one or more embodiments, before the connection electrode layer CNE is patterned, a second insulating layer INS2 may be patterned on the light emitting elements LD. After that, additional layers may be disposed on the light emitting elements LD, the connection electrode layer CNE, and the bank BNK, thereby manufacturing the display device DD in accordance with the embodiments of the present disclosure.

In accordance with the present disclosure, there can be provided a display device and a manufacturing method for a display device, which can improve process efficiency.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
a bank on a base layer, the bank forming an opening;
an alignment electrode layer on the base layer, the alignment electrode layer comprising a first alignment electrode and a second alignment electrode that are spaced from each other in a first direction; and
a light emitting element between the first alignment electrode and the second alignment electrode,
wherein the opening includes a first area and a second area,
wherein the first area and the second area are arranged along a second direction different from the first direction,
wherein the first area has a first width along the first direction, and the second area has a second width along the first direction, and
wherein the first width is greater than the second width.

2. The display device of claim 1, wherein the light emitting element comprises first light emitting elements and second light emitting elements,
wherein the display device further comprises an intermediate connection electrode electrically connecting the first light emitting elements and the second light emitting elements to each other,
wherein the first light emitting elements are electrically connected in parallel to each other,
wherein the second light emitting elements are electrically connected in parallel to each other,
wherein the first light emitting elements and the second light emitting elements are electrically connected in series to each other, and
wherein the intermediate connection electrode is located throughout the first area and the second area.

3. The display device of claim 2, wherein the intermediate connection electrode overlaps with the first area along the first direction.

4. The display device of claim 2, wherein each of the first light emitting elements and the second light emitting elements comprises a first end portion and a second end portion, and
wherein the first end portion of each of the first light emitting elements and the second light emitting elements faces the second alignment electrode, and
wherein the second end portion of each of the first light emitting elements and the second light emitting elements faces the first alignment electrode.

5. The display device of claim 1, wherein the light emitting element is not located in the first area and is located in the second area.

6. The display device of claim 1, wherein a direction in which the first area and the second area are arranged is different from a length direction of the light emitting element.

7. The display device of claim 1, wherein, in a plan view, the bank has an arch-shaped structure in an area overlapping with the second area along the first direction.

8. The display device of claim 1, wherein the bank protrudes in a thickness direction of the base layer, and comprises an organic material.

9. The display device of claim 1, wherein the light emitting element comprises first light emitting elements, second light emitting elements, third light emitting elements, and fourth light emitting elements in the second area without being in the first area, and are electrically connected in series with each other,
wherein the second area includes a (2-1)th area at one side of the first area and a (2-2)th area at an other side of the first area,
wherein the first light emitting elements and the fourth light emitting elements are in the (2-1)th area, and are spaced from each other in the first direction, and
wherein the second light emitting elements and the third light emitting elements are in the (2-1)th area, and are spaced from each other in the first direction.

10. The display device of claim 9, further comprising a connection electrode layer electrically connected to the light emitting element,
wherein the alignment electrode layer comprises a first electrode, a second electrode, a third electrode, and a fourth electrode that are sequentially located along the first direction, and each extends in the second direction,
wherein each of the first electrode and the fourth electrode is the first alignment electrode, and each of the second electrode and the third electrode is the second alignment electrode, and
wherein the connection electrode layer comprises an anode connection electrode in the (2-1)th area and is electrically connected to the first light emitting elements, a first intermediate connection electrode located throughout the (2-1)th area, the first area, and the (2-2)th area and is electrically connected to the first light emitting elements and the second light emitting elements, a second intermediate connection electrode in the (2-2)th area and is electrically connected to the second light emitting elements and the third light emitting elements, a third intermediate connection electrode located throughout the (2-1)th area, the first area, and the (2-2)th area and is electrically connected to the third light emitting elements and the fourth light emitting elements, and a cathode connection electrode electrically connected to the fourth light emitting elements.

11. A display device comprising:
a pixel circuit layer comprising a pixel circuit;
an alignment electrode layer on the pixel circuit layer;
a bank on the pixel circuit layer;
a light emitting element aligned on the alignment electrode layer; and
a connection electrode layer electrically connected to the light emitting element,
wherein the alignment electrode layer comprises a first electrode, a second electrode, a third electrode, and a fourth electrode that are sequentially located along a first direction, and extending in a second direction different from the first direction,
wherein the bank includes a first area and a second area that are spaced from each other in the second direction,
wherein the second area includes a (2-1)th area at one side of the first area and a (2-2)th area at an other side of the first area, and the first area is between the (2-1)th area and the (2-2)th area,
wherein the light emitting element comprises a first light emitting element, a second light emitting element, a third light emitting element, and a fourth light emitting element located in the second area without being located in the first area, and are electrically connected in series with each other,
wherein the connection electrode layer comprises an anode connection electrode in the (2-1)th area and is electrically connected to the first light emitting element, a first intermediate connection electrode located throughout the (2-1)th area, the first area, and the (2-2)th area and is electrically connected to the first light emitting element and the second light emitting element, a second intermediate connection electrode in the (2-2)th area and is electrically connected to the second light emitting element and the third light emitting element, a third intermediate connection electrode located throughout the (2-1)th area, the first area, and the (2-2)th area and is electrically connected to the third light emitting element and the fourth light emitting element, and a cathode connection electrode in the (2-1)th area and electrically connected to the fourth light emitting element, and
wherein, in a plan view, the bank has an arch-shaped structure in an area overlapping with the second area along the first direction.

12. A method for manufacturing a display device, the method comprising:
forming, on a base layer, an alignment electrode layer comprising a first alignment electrode and a second alignment electrode that are spaced from each other in a first direction, and a bank forming an opening;
providing an ink including a light emitting element in the opening;
performing a first drying process on the ink;
aligning the light emitting element between the first alignment electrode and the second alignment electrode; and
performing a second drying process on the ink.

13. The method of claim 12, wherein the first drying process is performed before the aligning, and
wherein the second drying process is performed after the aligning.

14. The method of claim 12, wherein the opening includes a first area and a second area,
wherein the first area and the second area are arranged along a second direction different from the first direction,
wherein the first area has a first width along the first direction, and the second area has a second width along the first direction, and
wherein the first width is greater than the second width.

15. The method of claim 14, further comprising forming a connection electrode layer electrically connected to the light emitting element,
wherein the light emitting element comprises first light emitting elements and second light emitting elements,
wherein the connection electrode layer comprises an intermediate connection electrode electrically connecting the first light emitting elements and the second light emitting elements to each other,
wherein the first light emitting elements are electrically connected in parallel to each other, and the second light emitting elements are electrically connected in parallel to each other,
wherein the first light emitting elements and the second light emitting elements are electrically connected in series to each other, and
wherein the intermediate connection electrode is located throughout the first area and the second area.

16. The method of claim 14, wherein the forming of the bank comprises:
forming a first bank part overlapping with the first area along the first direction; and
forming a second bank part overlapping with the second area along the first direction,
wherein the second bank part has an arch-shaped outer surface.

17. The method of claim 14, wherein the performing of the first drying process comprises removing the ink in the first area.

18. The method of claim 14, wherein the first drying process is performed until the ink is entirely removed in the first area.

19. The method of claim 17, wherein the performing of the first drying process comprises allowing the ink to remain in the second area, and
wherein the performing of the second drying process comprises removing the ink in the second area.

20. The method of claim 14, wherein the performing of the first drying process comprises allowing a capillary force in a direction toward the second area from the first area to be generated.
